(19) United States
(12) Patent Application Publication
(10) Pub. No.: US 2026/0004993 A1
(43) Pub. Date: Jan. 1, 2026

(54) PLASMA PROCESSING APPARATUS

(71) Applicant: Tokyo Electron Limited, Tokyo (JP)

(72) Inventor: Takahiro SHINDO, Tokyo (JP)

(21) Appl. No.: 19/242,900

(22) Filed: Jun. 18, 2025

(30) Foreign Application Priority Data
Jun. 27, 2024 (JP) 2024-104134

(51) Int. Cl. H01J 37/32; C23C 16/455; H01F 27/24; H01F 27/28

(52) U.S. Cl. CPC H01J 37/3211; C23C 16/45544; H01F 27/24; H01F 27/28; H01J 2237/332

(57) ABSTRACT

A plasma processing apparatus includes a processing container, a substrate holder that holds a substrate and accommodated inside the processing container, and a plasma generation mechanism that generates an inductively-coupled plasma. The plasma generation mechanism includes a discharge chamber having a loop shape, an antenna including a magnetic core and a coil wound around the magnetic core, the antenna generating an induced current in the discharge chamber, and a radio-frequency power supply that supplies radio-frequency power to the coil.

### CROSS-REFERENCE TO RELATED APPLICATIONS

This application is based on and claims priority from Japanese Patent Application No. 2024-104134, filed on Jun. 27, 2024, with the Japan Patent Office, the disclosure of which is incorporated herein in its entirety by reference.

### TECHNICAL FIELD

The present disclosure relates to a plasma processing apparatus.

### BACKGROUND

Japanese Patent Laid-Open Publication No. 2011-097096 discloses a plasma processing apparatus that performs a plasma processing on a processing target object, the apparatus including a cylindrical processing container capable of being evacuated, a holder that is inserted into or removed from the processing container while holding a plurality of processing target objects, a gas supply that supplies a gas into the processing container, and an activator that activates the gas using a plasma. The activator includes a plasma generation box provided along the longitudinal direction of the processing container, an inductively-coupled electrode provided along the plasma generation box, and a radio-frequency power supply connected to the inductively-coupled electrode.

### SUMMARY

According to an aspect, a plasma processing apparatus includes a processing container, a substrate holder that holds a substrate and is accommodated inside the processing container, and a plasma generation mechanism that generates an inductively-coupled plasma. The plasma generation mechanism includes a discharge chamber having a loop shape, an antenna that includes a magnetic core and a coil wound around the magnetic core, and generates an induced current in the discharge chamber, and a radio-frequency power supply that supplies radio-frequency power to the coil.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic diagram illustrating a configuration example of a substrate processing apparatus.

FIG. 2 is a schematic diagram illustrating a configuration example of a plasma generation mechanism according to a first embodiment.

FIG. 3 is a schematic plan view illustrating the configuration example of the plasma generation mechanism according to the first embodiment.

FIG. 4 is a graph illustrating the excitation current of a coil.

FIG. 5 is a schematic diagram illustrating a configuration example of a plasma generation mechanism according to a modification of the first embodiment.

FIG. 6 is a schematic horizontal cross-sectional view illustrating the configuration example of the plasma generation mechanism according to the modification of the first embodiment.

FIG. 7 is a schematic diagram illustrating a configuration example of a plasma generation mechanism according to another modification of the first embodiment.

FIG. 8 is a schematic horizontal cross-sectional view illustrating the configuration example of the plasma generation mechanism according to the other modification of the first embodiment.

FIG. 9 a schematic diagram illustrating a configuration example of a plasma generation mechanism according to a second embodiment.

FIG. 10 is a schematic horizontal cross-sectional view illustrating the configuration example of the plasma generation mechanism according to the second embodiment.

FIG. 11 is a schematic diagram illustrating a configuration example of a plasma generation mechanism according to a third embodiment.

FIG. 12 is a schematic horizontal cross-sectional view illustrating the configuration example of the plasma generation mechanism according to the third embodiment.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, embodiments for implementing the present disclosure will be described with reference to the drawings. In each drawing, the same reference numerals may be given to the same components, and redundant descriptions may be omitted.

### [Substrate Processing Apparatus]

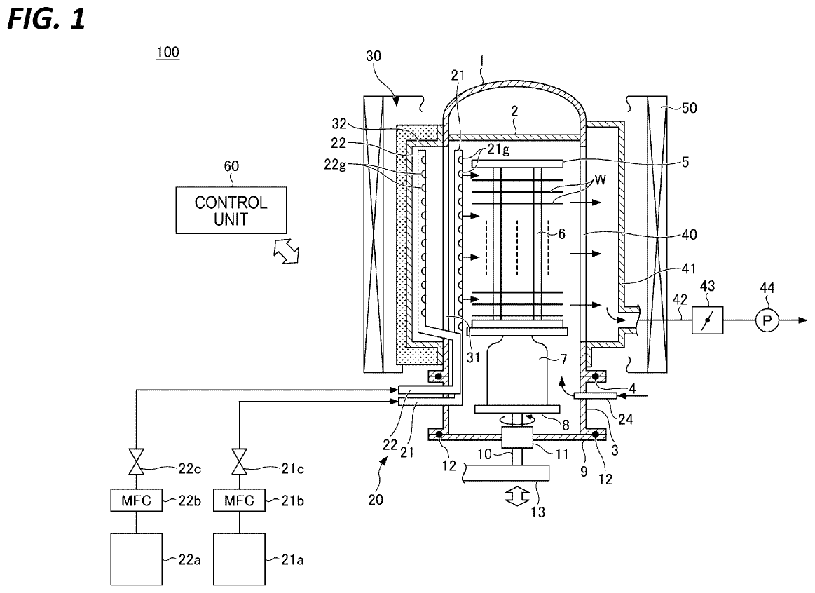

A substrate processing apparatus (plasma processing apparatus) 100 according to the present embodiment will be described with reference to FIG. 1. FIG. 1 is a schematic diagram illustrating a configuration example of the substrate processing apparatus 100. In the following description, the substrate processing apparatus 100 will be described as a film forming apparatus that forms a silicon nitride film on a substrate W by an atomic layer deposition (ALD) process, for example, using a plasma of a silicon-containing gas and a nitrogen-containing gas.

The substrate processing apparatus 100 includes a ceilinged cylindrical processing container 1 with a bottom opening. The entire processing container 1 is made of, for example, quartz. A ceiling plate 2, made of quartz, is provided near the top inside the processing container 1, and a region under the ceiling plate 2 is sealed. A cylindrically-molded metallic manifold 3 is connected to the bottom opening of the processing container 1 via a seal member 4 such as an O-ring.

The manifold 3 supports the bottom of the processing container 1, and a wafer boat 5 (substrate holder), on which a large number (e.g., 25 to 150) of semiconductor wafers (hereinafter referred to as a ‘substrate W”) are stacked in multiple stages, is inserted into the processing container 1 from below the manifold 3. In this way, a large number of substrates W are accommodated approximately horizontally with spacing along the vertical direction inside the processing container 1. The wafer boat 5 is made of, for example, quartz. The wafer boat 5 includes three rods 6 (two rods are illustrated in FIG. 1), and the large number of substrates W are supported by grooves (not illustrated) formed in the rods 6.

The wafer boat 5 is disposed on a table 8 via a heat reservoir 7 made of quartz. The table 8 is supported on a rotating shaft 10, which penetrates a metallic (stainless steel) lid 9 that opens or closes a bottom opening of the manifold 3.

A magnetic fluid seal 11 is provided around a penetrating portion of the rotating shaft 10 to airtightly seal and rotatably support the rotating shaft 10. A seal member 12 is provided between a peripheral portion of the lid 9 and the bottom of the manifold 3 to maintain airtightness inside the processing container 1.

The rotating shaft 10 is attached to the tip of an arm 13, which is supported by an elevating mechanism (not illustrated) such as, for example, a boat elevator. The wafer boat 5 and the lid 9 are integrally moved up and down and are inserted into or removed from the processing container 1. The table 8 may be fixedly provided on the lid 9 side, such that the substrates W are processed without rotating the wafer boat 5.

Further, the substrate processing apparatus 100 includes a gas supply unit 20 (processing gas supply) that supplies predetermined gases such as a processing gas and a purge gas into the processing container 1.

The gas supply unit 20 includes gas supply pipes 21, 22 and 24. The gas supply pipe 21 is made of, for example, quartz, and inwardly penetrates the sidewall of the manifold 3 and is then bent upward to extend vertically. A plurality of gas holes 21g is formed at predetermined intervals in a vertical portion of the gas supply pipe 21 over a vertical length corresponding to the wafer support range of the wafer boat 5. Each gas hole 21g discharges a gas in the horizontal direction. The gas supply pipe 22 is made of, for example, quartz, and inwardly penetrates the sidewall of the manifold 3 and is then bent upward to extend vertically. A plurality of gas holes 22g is formed at predetermined intervals in a vertical portion of the gas supply pipe 22 over a vertical length corresponding to the wafer support range of the wafer boat 5. Each gas hole 22g discharges a gas in the horizontal direction. The gas supply pipe 24 is made of, for example, quartz, and is formed as a short quartz pipe provided to penetrate the sidewall of the manifold 3.

The vertical portion (i.e., vertical portion formed with the gas holes 21g) of the gas supply pipe 21 is located inside the processing container 1. A processing gas (e.g., source gas) is supplied to the gas supply pipe 21 from a gas supply source 21a through gas piping. The gas piping is provided with a flow-rate controller 21b and an on-off valve 21c. Thus, the processing gas from the gas supply source 21a is supplied into the processing container 1 through the gas piping and the gas supply pipe 21. The processing gas supplied from the gas supply source 21a is, for example, a precursor gas that is adsorbed onto the substrate W such as, for example, a silicon-containing gas. The silicon-containing gas is, for example, dichlorosilane (DCS, SiH₂Cl₂).

The vertical portion (i.e., vertical portion formed with the gas holes 22g) of the gas supply pipe 22 is located in a plasma generation space to be described later. A processing gas (e.g., reaction gas) is supplied to the gas supply pipe 22 from a gas supply source 22a through gas piping. The gas piping is provided with a flow-rate controller 22b and an on-off valve 22c. Thus, the processing gas from the gas supply source 22a is supplied to the plasma generation space through the gas piping and gas supply pipe 22, and in the plasma generation space, the gas forms a plasma to be supplied into the processing container 1. The processing gas supplied from the gas supply source 22a is a reaction gas that reacts with the precursor gas adsorbed onto the substrate W to form a film (e.g., a silicon nitride film) such as, for example, a nitrogen-containing gas. The nitrogen-containing gas is, for example, NH₃.

The processing gas (source gas) supplied from the gas supply source 21a and the processing gas (reaction gas) supplied from the gas supply source 22a are not limited to those mentioned above.

A purge gas is supplied to the gas supply pipe 24 from a purge gas supply source (not illustrated) through gas piping. The gas piping (not illustrated) is provided with a flow-rate controller (not illustrated) and an on-off valve (not illustrated). Thus, the purge gas from the purge gas supply source is supplied into the processing container 1 through the gas piping and gas supply pipe 24. The purge gas supplied from the purge gas supply source is, for example, an inert gas such as argon (Ar) or nitrogen (N₂). Further, a case where the purge gas is supplied into the processing container 1 through the gas supply pipe 24 has been described, but this is not limiting. The purge gas may also be supplied into the processing container 1 through either the gas supply pipe 21 or 22.

A plasma generation mechanism 30 is formed on a portion of the sidewall of the processing container 1. The plasma generation mechanism 30 forms a plasma from the processing gas (reaction gas) from the gas supply source 22a.

The plasma generation mechanism 30 generates an inductively-coupled plasma ICP of the processing gas supplied from the gas supply pipe 22, thereby generating active species (radicals) of the processing gas.

A discharge chamber 32 is airtightly welded to the outer wall of the processing container 1. The discharge chamber 32 is made of, for example, quartz. The discharge chamber 32 covers an opening 31 formed in the sidewall of the processing container 1. The opening 31 is formed in an elongated vertical shape so as to cover all the substrates W supported by the wafer boat 5 in the vertical direction. The gas supply pipe 22 for discharging the processing gas is arranged in an inner space, i.e., the plasma generation space, defined by the discharge chamber 32 and communicating with the inside of the processing container 1. The gas supply pipe 21 for discharging the processing gas is provided at a position close to the substrates W along the inner sidewall of the processing container 1 outside the plasma generation space.

Further, the plasma generation mechanism 30 generates an inductively-coupled plasma (ICP) by supplying radio-frequency power from a radio-frequency power supply to an antenna. The discharge chamber 32 may be structured to keep a sufficient distance from the substrates W so that the plasma generated in the discharge chamber 32 does not come into contact with the substrates W. Further, it may have a remote plasma configuration in which an ion trap is provided in the opening 31 to supply radicals to the processing container 1. Alternatively, it may have a direct plasma configuration in which the plasma generated in the discharge chamber 32 directly comes into contact with the substrates W.

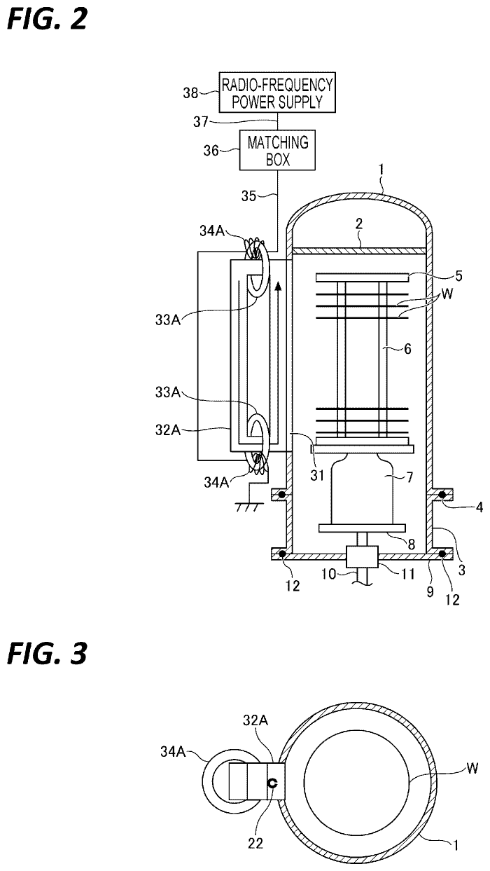

Details of the plasma generation mechanism 30 will be described later with reference to FIGS. 2 and 3.

An exhaust port 40 (exhauster) for evacuating the inside of the processing container 1 is provided on a sidewall portion of the processing container 1 opposite the opening 31. The exhaust port 40 is formed in a vertically elongated shape to correspond to the wafer boat 5. An exhaust port cover member 41, molded into a U-shaped cross-sectional shape, is attached to a portion of the processing container 1 corresponding to the exhaust port 40 so as to cover the exhaust port 40. The exhaust port cover member 41 extends upward along the sidewall of the processing container 1. An exhaust pipe 42 for evacuating the processing container 1 through the exhaust port 40 is connected to a lower portion of the exhaust port cover member 41. The exhaust pipe 42 is connected to a pressure control valve 43 for controlling the pressure inside the processing container 1 and an exhaust device 44 including, for example, a vacuum pump, so that the inside of the processing container 1 is evacuated through the exhaust pipe by the exhaust device 44.

A cylindrical heating mechanism 50 is provided around the processing container 1. The heating mechanism 50 heats the processing container 1 and the substrates W in the inside of the processing container 1. The heating mechanism 50 controls the temperature of the processing container 1 to reach a desired temperature. Thus, the substrates W inside the processing container 1 are heated by, for example, radiant heat from the wall surface of the processing container 1.

Further, the substrate processing apparatus 100 includes a control unit 60. The control unit 60 controls, for example, operations of various components of the substrate processing apparatus 100, such as the supply and stoppage of gases by the opening and closing of the on-off valves 21c and 22c, the gas flow-rate control through the flow-rate controllers 21b and 22b, and the exhaust control using the exhaust device 44. Further, the control unit 60 performs, for example, ON/OFF control of radio-frequency power by the radio-frequency power supply 38 (see, e.g., FIG. 2 described later) of the plasma generation mechanism 30 and the temperature control of the processing container 1 and the substrates W inside the processing container by the heating mechanism 50.

The control unit 60 may be, for example, a computer, among others. Further, a computer program that executes the operations of various components of the substrate processing apparatus 100 is stored in a storage medium. The storage medium may be, for example, a flexible disk, compact disk, hard disk, flash memory, DVD, or similar device.

### [Substrate Processing Process of Substrate Processing Apparatus]

Next, the operation of the substrate processing apparatus 100 will be described.

First, the substrate W is prepared. Here, the wafer boat 5 on which the substrate W is disposed is inserted into the processing container 1.

Next, a source gas is supplied. Here, the control unit 60 controls the flow-rate controller 21b and the on-off valve 21c to supply the source gas from the gas supply source 21a into the processing container 1. Thus, for example, the source gas is adsorbed onto the surface of the substrate W.

Next, an inductively-coupled plasma of a reaction gas is generated. Here, the control unit 60 controls the flow-rate controller 22b and the on-off valve 22c to supply a reaction gas from the gas supply source 22a into the plasma generation space. Further, the control unit 60 controls the radio-frequency power supply 38 described later to supply radio-frequency power to a coil provided in the plasma generation mechanism 30. Thus, the reaction gas discharged from the gas supply pipe 22 forms a plasma within the plasma generation space, and active species such as radicals are supplied to the inside of the processing container 1 through the opening 31. Thus, for example, the active species (such as radicals) of the reaction gas react with the source gas adsorbed onto the surface of the substrate W, thereby forming a film on the surface of the substrate W.

Then, the step of supplying the source gas and the step of generating the plasma from the reaction gas to perform a processing on the substrate W constitute one cycle, and by repeating this cycle a predetermined number of times, a film with a desired film thickness is formed on the substrate W.

Here, in comparison with a substrate processing apparatus that uses a capacitively-coupled plasma (CCP), the substrate processing apparatus 100 that uses an inductively-coupled plasma (ICP) may achieve a higher plasma density and supply a large amount of radicals to the substrate W. Further, in a substrate processing apparatus that uses a capacitively-coupled plasma (CCP), ions are drawn toward an electrode, thus colliding with the wall surface of the discharge chamber 32 and resulting in sputtering, which may lead to wall surface erosion or particle generation. In contrast, in the substrate processing apparatus 100 that uses an inductively-coupled plasma (ICP), it is possible to prevent wall surface erosion and particle generation.

However, in order to generate an inductively-coupled plasma (ICP), it is necessary to flow a high current through a coil to form a sufficient magnetic field, compared to a capacitively-coupled plasma (CCP). Further, as illustrated in FIG. 1, the processing container 1 and the plasma generation mechanism 30 (discharge chamber 32) are stored inside the heating mechanism 50. Therefore, materials with good electrical conductivity but low heat resistance, such as copper, may not be suitable for use as the electrode material of the coil.

Further, when using a heat-resistant metal (e.g., Inconel®) as the electrode material of the coil, the electrical resistivity thereof is higher than that of copper, and therefore, most of the input power may be consumed as heat generation in the coil, making it difficult to supply sufficient power to the coil to generate an inductively-coupled plasma (ICP).

### First Embodiment

Next, the substrate processing apparatus 100 equipped with the plasma generation mechanism 30 according to a first embodiment will be described with reference to FIGS. 2 and 3. FIG. 2 is a schematic diagram illustrating a configuration example of the plasma generation mechanism 30 according to a first embodiment. FIG. 3 is a schematic plan view illustrating the configuration example of the plasma generation mechanism 30 according to the first embodiment.

The plasma generation mechanism 30 according to the first embodiment includes a discharge chamber 32A, a toroidal core 33A, a coil 34A, a power supply line 35, a coaxial cable 37, and a radio-frequency power supply 38.

The discharge chamber 32A is formed such that the internal space thereof loops. In the example illustrated in FIG. 2, the discharge chamber 32A is formed to loop in the height direction. In other words, the discharge chamber 32A has an internal space that loops around a horizontal axis. For example, the discharge chamber 32A includes a first internal space extending in the height direction on the processing container 1 side, a second internal space extending in the height direction on the side away from the processing container 1, a third internal space extending horizontally to interconnect the top of the first internal space and the top of the second internal space, and a fourth internal space extending horizontally to interconnect the bottom of the second internal space and the bottom of the first internal space. Thus, the discharge chamber 32A is formed to loop in the order of the first internal space, third internal space, second internal space, and fourth internal space. The opening 31 is provided between the first internal space and the processing container 1, and the internal space of the discharge chamber 32A communicates with the internal space of the processing container 1. The gas supply pipe 22 may be placed in the first internal space where the opening 31 is provided, as illustrated in FIG. 3. This allows the gas supplied into the processing container 1 through the opening 31 to achieve a more uniform flow rate distribution in the height direction, compared to a case where the gas supply pipe 22 is arranged in the second internal space.

The toroidal core 33A is made of a magnetic material and is formed in an annular shape (e.g., a ring or loop shape) having a through-hole at the center thereof. The toroidal core (33A) is arranged such that the discharge chamber 32A is inserted through the through-hole thereof. At least one toroidal core 33A may be provided. Further, the toroidal core 33A is illustrated as being arranged such that the aforementioned third internal space of the discharge chamber 32A is inserted through the through-hole of the toroidal core 33A and the aforementioned fourth internal space of the discharge chamber 32A is inserted through the through-hole of the toroidal core 33A, but this is not limiting. The aforementioned first internal space of the discharge chamber 32A may be inserted through the through-hole of the toroidal core 33A and the aforementioned second internal space of the discharge chamber 32A may be inserted through the through-hole of the toroidal core 33A.

The coil 34A is wound in a helical shape around the toroidal core 33A. The toroidal core 33A and the coil 34A constitute an antenna.

The power supply line 35 electrically interconnects the coil 34A and a matching box 36. The matching box 36 is a device for impedance matching. The coaxial cable 37 electrically interconnects the matching box 36 and the radio-frequency power supply 38. The radio-frequency power supply 38 is connected to the antenna (coil 34A) via the coaxial cable 37, matching box 36, and power supply line 35, and supplies radio-frequency power thereto.

By supplying power to the coil 34A, an annular magnetic flux is generated in the inside of the toroidal core 33A. Then, a looped induced current (indicated by a solid arrow in FIG. 2) is generated in the looped discharge chamber 32A. This induced current generates an inductively-coupled plasma (ICP) in the discharge chamber 32A.

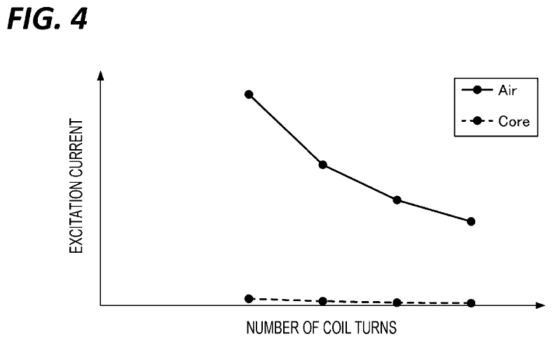

Here, a magnetic core will be described with reference to FIG. 4. FIG. 4 is a graph illustrating the excitation current of a coil. The horizontal axis represents the number of coil turns, and the vertical axis represents the simulation result of excitation current required to generate a certain induced electric field. Further, the result for an air-core coil (Air) is represented by a solid line, and the result for a coil having a magnetic core (Core) is represented by a dashed line.

As illustrated in FIG. 4, the excitation current is greatly reduced in the coil having a magnetic core (Core), compared to the air-core coil (Air). This indicates that, by using a magnetic core (toroidal core 33A), an inductively-coupled plasma (ICP) may be generated using the coil 34A made of a material with higher heat resistance and higher electrical resistivity than copper.

Any of Mn—Zn-based ferrite, Ni—Zn-based ferrite, and Fe-powder-based cores may be used as the material of the magnetic core (toroidal core 33A). Mn—Zn-based ferrite and Ni—Zn-based ferrite cores may be used at a temperature of 300° C. or lower, while Fe-powder-based cores may be used at a temperature of 700° C. or lower.

Further, magnetic flux leakage may be prevented by using the annular toroidal core 33A. In other words, preventing magnetic flux leakage allows the excitation current required to generate a certain induced electric field to be reduced.

Further, a heat-resistant metal such as a nickel alloy (specifically, Inconel®, Hastelloy®, or Nimonic®) may be used as the material of the coil.

### Modification of First Embodiment

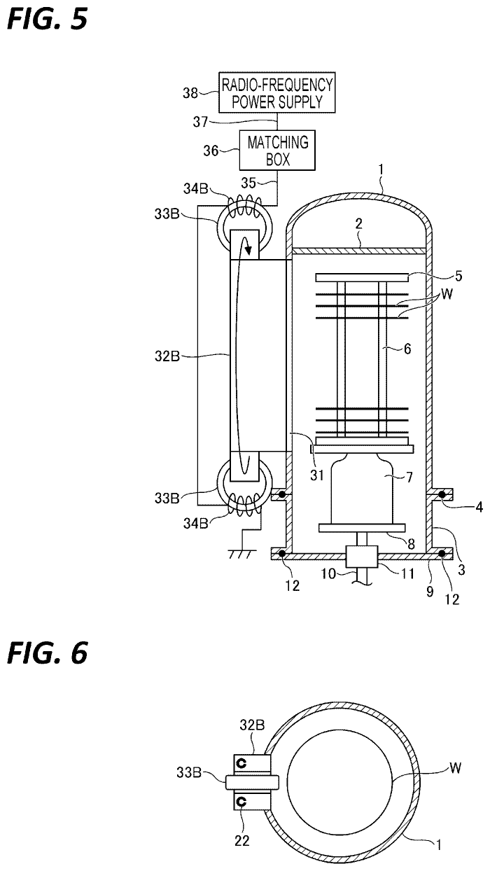

Next, the substrate processing apparatus 100 equipped with the plasma generation mechanism 30 according to a modification of the first embodiment will be described with reference to FIGS. 5 and 6. FIG. 5 is a schematic diagram illustrating a configuration example of the plasma generation mechanism 30 according to a modification of the first embodiment. FIG. 6 is a schematic horizontal cross-sectional view illustrating the configuration example of the plasma generation mechanism according to the modification of the first embodiment.

The plasma generation mechanism 30 according to the modification of the first embodiment includes a discharge chamber 32B, a toroidal core 33B, a coil 34B, the power supply line 35, the coaxial cable 37, and the radio-frequency power supply 38. The plasma generation mechanism 30 according to the modification of the first embodiment (see, e.g., FIGS. 5 and 6) differs from the plasma generation mechanism 30 according to the first embodiment (see, e.g., FIGS. 2 and 3) in the direction of the looped induced current.

The discharge chamber 32B is formed such that the internal space thereof loops. In the example illustrated in FIG. 5, the discharge chamber 32B is formed to loop in the height direction. In other words, the discharge chamber 32B has an internal space that loops around a horizontal axis. For example, the discharge chamber 32B includes a first internal space extending in the height direction on the front side of the page of FIG. 5, a second internal space extending in the height direction on the rear side of the page of FIG. 5, a third internal space extending horizontally to interconnect the top of the first internal space and the top of the second internal space, and a fourth internal space extending horizontally to interconnect the bottom of the second internal space and the bottom of the first internal space. Thus, the discharge chamber 32B is formed to loop in the order of the first internal space, third internal space, second internal space, and fourth internal space. The opening 31 is provided between the first and second internal spaces and the processing container 1, and the internal space of the discharge chamber 32B communicates with the internal space of the processing container 1. The gas supply pipe 22 may be arranged in the first and second internal spaces, as illustrated in FIG. 6.

The toroidal core 33B is made of a magnetic material and is formed in an annular shape (e.g., a ring or loop shape) having a through-hole at the center thereof. The toroidal core 33B is arranged such that the discharge chamber 32B is inserted through a through-hole thereof. At least one toroidal core 33B may be provided. Further, the toroidal core 33B is illustrated as being arranged such that the aforementioned third internal space of the discharge chamber 32B is inserted through the through-hole of the toroidal core 33B and the aforementioned fourth internal space of the discharge chamber 32B is inserted through the through-hole of the toroidal core 33B, but this is not limiting. The aforementioned first internal space of the discharge chamber 32B may be inserted through the through-hole of the toroidal core 33B and the aforementioned second internal space of the discharge chamber 32B may be inserted through the through-hole of the toroidal core 33B.

The coil 34A is wound in a helical shape around the toroidal core 33A. The toroidal core 33B and the coil 34B constitute an antenna.

The power supply line 35 electrically interconnects the coil 34A and the matching box 36. The matching box 36 is a device for impedance matching. The coaxial cable 37 electrically interconnects the matching box 36 and the radio-frequency power supply 38. The radio-frequency power supply 38 is connected to the antenna (coil 34B) via the coaxial cable 37, matching box 36, and power supply line 35, and supplies radio-frequency power thereto.

By supplying power to the coil 34B, an annular magnetic flux is generated in the inside of the toroidal core 33B. Then, a looped induced current (indicated by a solid arrow in FIG. 5) is generated in the looped discharge chamber 32B. This induced current generates an inductively-coupled plasma (ICP) in the discharge chamber 32B.

### Another Modification of First Embodiment

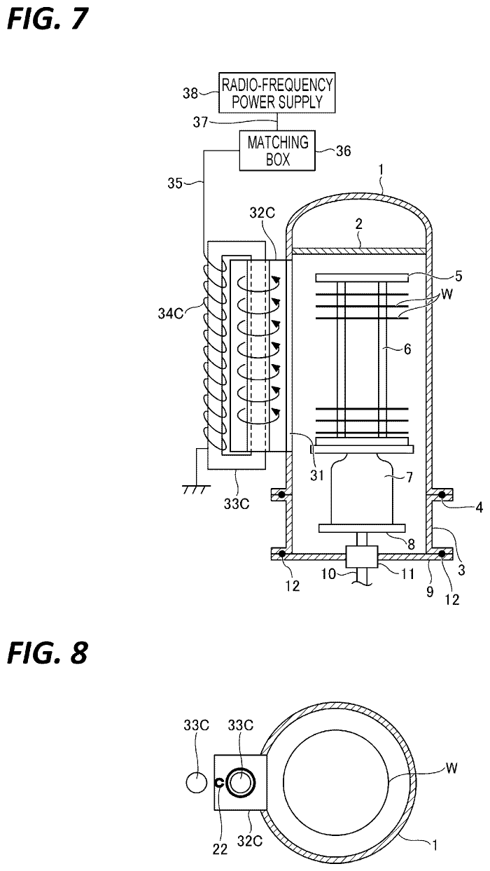

Next, the substrate processing apparatus 100 equipped with the plasma generation mechanism 30 according to a modification of the first embodiment will be described with reference to FIGS. 7 and 8. FIG. 7 is a schematic diagram illustrating a configuration example of the plasma generation mechanism 30 according to another modification of the first embodiment. FIG. 8 is a schematic horizontal cross-sectional view illustrating the configuration example of the plasma generation mechanism according to the other modification of the first embodiment. The plasma generation mechanism 30 according to the other modification of the first embodiment (see, e.g., FIGS. 7 and 8) differs from the plasma generation mechanism 30 according to the first embodiment (see, e.g., FIGS. 2 and 3) in the direction of the looped induced current.

The plasma generation mechanism 30 according to the other modification of the first embodiment includes a discharge chamber 32C, a toroidal core 33C, a coil 34C, the power supply line 35, the coaxial cable 37, and the radio-frequency power supply 38.

The discharge chamber 32C is formed such that the internal space thereof loops. In the example illustrated in FIG. 7, the discharge chamber 32C has a cylindrical internal space and is formed to loop in the horizontal direction. In other words, the discharge chamber 32C has an internal space that loops around a vertical axis. For example, the discharge chamber 32C has a through-hole that penetrates in the height direction. Further, the gas supply pipe 22 is provided on the opposite side of the opening 31 as viewed from the through-hole of the discharge chamber 32C. Since the discharge chamber 32C has a cylindrical internal space, it is possible to make the flow rate distribution at the height position of the gas supplied from the opening 31 into the processing container 1 uniform even if the gas supply pipe 22 is provided at this position.

The toroidal core 33C is made of a magnetic material and is formed in an annular (loop) shape. The toroidal core 33C is arranged such that the discharge chamber 32C is inserted through a through-hole thereof. Here, the toroidal core 33C includes a first portion that extends in the height direction and is inserted through the through-hole of the discharge chamber 32C, a second portion that extends in the height direction outside the discharge chamber 32C, a third portion that interconnects the top of the first portion and the top of the second portion, and a fourth portion that interconnects the bottom of the first portion and the bottom of the second portion. Thus, the toroidal core 33C is formed to loop in the order of the first portion, third portion, second portion, and fourth portion.

The coil 34C is wound in a helical shape around the toroidal core 33C. Specifically, it is wound around the second portion of the toroidal core 33C. Further, the toroidal core 33C and the coil 34C constitute an antenna.

The power supply line 35 electrically interconnects the coil 34A and the matching box 36. The matching box 36 is a device for impedance matching. The coaxial cable 37 electrically interconnects the matching box 36 and the radio-frequency power supply 38. The radio-frequency power supply 38 is connected to the antenna (coil 34C) via the coaxial cable 37, matching box 36, and power supply line 35, and supplies radio-frequency power thereto.

By supplying power to the coil 34C, an annular magnetic flux is generated in the inside of the toroidal core 33C. Then, a first portion of the coil 34C is located in the through-hole of the discharge chamber 32C, and a magnetic flux is generated in the height direction. Thus, a looped induced current (indicated by solid arrows in FIG. 7) is generated in the discharge chamber 32C. This induced current generates an inductively-coupled plasma (ICP) in the discharge chamber 32C.

### Second Embodiment

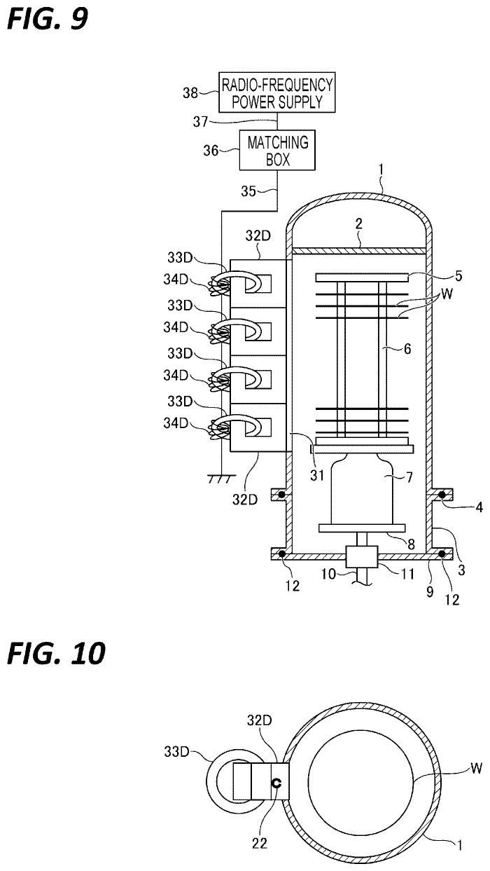

Next, the substrate processing apparatus 100 equipped with the plasma generation mechanism 30 according to a second embodiment will be described with reference to FIGS. 9 and 10. FIG. 9 is a schematic diagram illustrating a configuration example of the plasma generation mechanism 30 according to a second embodiment. FIG. 10 is a schematic horizontal cross-sectional view illustrating the configuration example of the plasma generation mechanism 30 according to the second embodiment.

The plasma generation mechanism 30 according to the second embodiment includes a discharge chamber 32D, a toroidal core 33D, a coil 34D, the power supply line 35, the coaxial cable 37, and the radio-frequency power supply 38.

In the plasma generation mechanism 30 according to the second embodiment, the discharge chamber 32D is divided in the height direction to form a plurality of discharge chambers. Further, an antenna including the toroidal core 33D and the coil 34D is arranged for each discharge chamber 32D. The other components are similar to those in the plasma generation mechanism 30 according to the first embodiment (see, e.g., FIGS. 2 and 3), and redundant descriptions are omitted. Further, a configuration has been described in which the single matching box 36 and the single radio-frequency power supply 38 supply power to each coil 34D in the example of FIG. 8, but this is not limiting. A plurality of matching boxes 36 and a plurality of radio-frequency power supplies 38 may be provided to correspond to the respective discharge chambers 32D. Further, the gas supply pipe 22 may also be provided for each discharge chamber 32D.

With this configuration, the amount of radicals supplied from each discharge chamber 32D to the processing container 1 may be individually adjusted. In other words, the distribution of radicals supplied to the processing container 1 may be adjusted in the height direction.

The direction of the induced current generated in each discharge chamber 32D has been described as being the same as in FIGS. 2 and 3, but this is not limiting. The direction of the induced current may be the same as in FIGS. 5 and 6, or may be the same as in FIGS. 7 and 8.

### Third Embodiment

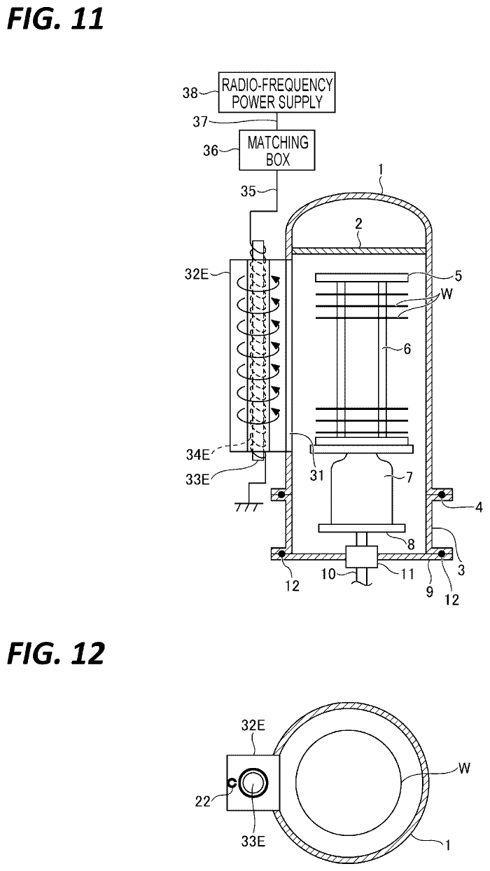

Next, the substrate processing apparatus 100 equipped with the plasma generation mechanism 30 according to a third embodiment will be described with reference to FIGS. 11 and 12. FIG. 11 is a schematic diagram illustrating a configuration example of the plasma generation mechanism 30 according to a third embodiment. FIG. 12 is a schematic horizontal cross-sectional view illustrating the configuration example of the plasma generation mechanism according to the third embodiment.

The plasma generation mechanism 30 according to the third embodiment includes a discharge chamber 32E, a rod core 33E, a coil 34E, the power supply line 35, the coaxial cable 37, and the radio-frequency power supply 38.

The discharge chamber 32E is formed such that the internal space thereof loops. In the example illustrated in FIG. 11, the discharge chamber 32E has a cylindrical internal space and is formed to loop in the horizontal direction. In other words, the discharge chamber 32E has an internal space that loops around a vertical axis. For example, the discharge chamber 32E has a through-hole that penetrates in the height direction. Further, the gas supply pipe 22 is provided on the opposite side of the opening 31 as viewed from the through-hole of the discharge chamber 32E. Since the discharge chamber 32E has a cylindrical internal space, it is possible to make the flow rate distribution at the height position of the gas supplied from the opening 31 into the processing container 1 uniform even if the gas supply pipe 22 is provided at this position.

The rod core 33E is made of a magnetic material and is formed in a rod shape. The rod core 33E is located in the through-hole of the discharge chamber 32E.

The coil 34E is wound in a helical shape around the rod core 33E. Further, the rod core 33E and the coil 34E constitute an antenna. In other words, the rod core 33E with the coil 34E wound thereon is located in the through-hole of the discharge chamber 32E.

The power supply line 35 electrically interconnects the coil 34E and the matching box 36. The matching box 36 is a device for impedance matching. The coaxial cable 37 electrically interconnects the matching box 36 and the radio-frequency power supply 38. The radio-frequency power supply 38 is connected to the antenna (coil 34E) via the coaxial cable 37, matching box 36, and power supply line 35, and supplies radio-frequency power thereto.

By supplying power to the coil 34E, a magnetic flux is generated in the height direction in the rod core 33E. Thus, a looped induced current (indicated by solid arrows in FIG. 11) is generated in the discharge chamber 32E. This induced current generates an inductively-coupled plasma (ICP) in the discharge chamber 32E.

According to the plasma generation mechanism 30 of the third embodiment, the structure may be simplified compared to other embodiments (see, e.g., FIGS. 2, 3, and 5 to 10) in which the loop-structured core and the loop-structured discharge chamber are configured to interpenetrate each other's through-holes. Further, the weight of the magnetic core may be reduced compared to the case illustrated in FIGS. 7 and 8.

Further, if a magnetic material with high heat resistance and low permeability is used as the core material, magnetic flux leakage may occur even with a loop-shaped core. In contrast, according to the plasma generation mechanism 30 of the third embodiment, by inserting the rod core 33E with the coil 34E wound directly thereon into the through-hole of the discharge chamber 32E, a desired magnetic flux may be generated in the through-hole of the discharge chamber 32E, and an induced current may be generated in the looped discharge chamber 32E, thereby generating a plasma.

According to an aspect, it is possible to provide a plasma processing apparatus for generating an inductively-coupled plasma.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A plasma processing apparatus comprising:
a processing container;
a substrate holder configured to hold a substrate and accommodated inside the processing container; and
a plasma generator configured to generate an inductively-coupled plasma,
wherein the plasma generator includes:
a discharge chamber having a loop shape;
an antenna including a magnetic core and a coil wound around the magnetic core, and configured to generate an induced current in the discharge chamber; and
a radio-frequency power supply configured to supply radio-frequency to the coil.

2. The plasma processing apparatus according to claim 1, wherein the discharge chamber has an internal space that loops around a horizontal axis.

3. The plasma processing apparatus according to claim 2, wherein the magnetic core is an annular toroidal core, and
a portion of the internal space is inserted through a through-hole formed at a center of the toroidal core.

4. The plasma processing apparatus according to claim 1, wherein the discharge chamber has an internal space that loops around a vertical axis.

5. The plasma processing apparatus according to claim 4, wherein the magnetic core is an annular toroidal core, and
a portion of the internal space is inserted through a through-hole formed at a center of the toroidal core.

6. The plasma processing apparatus according to claim 5, wherein the magnetic core is a rod core having a rod shape, and
the discharge chamber has a through-hole penetrating in a height direction, and
the rod core with the coil wound thereon is located in the through-hole of the discharge chamber.

7. The plasma processing apparatus according to claim 1, wherein the discharge chamber is divided into a plurality of sections in a height direction.

8. The plasma processing apparatus according to claim 1, wherein the magnetic core is made of any one of Mn—Zn-based ferrite, Ni—Zn-based ferrite, and Fe-powder-based cores.

9. The plasma processing apparatus according to claim 1, wherein the coil is made of a nickel alloy.
